(19) United States
(12) Patent Application Publication
(10) Pub. No.: US 2013/0276860 A1
(43) Pub. Date: Oct. 24, 2013

(54) SOLAR BATTERY CELL, MANUFACTURING METHOD THEREOF, AND SOLAR BATTERY MODULE

(71) Applicant: Shoichi Karakida, Chiyoda-ku (JP)

(72) Inventor: Shoichi Karakida, Chiyoda-ku (JP)

(73) Assignee: Mitsubishi Electric Corporation, Chiyoda-ku, Tokyo (JP)

(21) Appl. No.: 13/976,711

(22) PCT Filed: Feb. 1, 2011
(86) PCT No.: PCT/JP2011/052040

§ 371 Date: Jun. 27, 2013

(51) Int. Cl. H01L 31/0236

(52) U.S. Cl. CPC H01L 31/02363
USPC 136/244; 136/255; 438/71

(57) ABSTRACT

A solar battery cell includes a semiconductor substrate of a first conduction type that includes a dopant diffusion layer on one surface side, a dopant element of a second conduction type being diffused into the dopant diffusion layer, a light-receiving surface side electrode formed on the one surface side of the semiconductor substrate, and a back surface side electrode that is formed on the other surface side of the semiconductor substrate, and a first irregular shape is provided on a surface on the other surface side of the semiconductor substrate, a second irregular shape lower in an optical reflectivity than the first irregular shape is provided on at least a part of a surface on the one surface side of the semiconductor substrate, and the one surface side of the semiconductor substrate is lower in the optical reflectivity than that on the other surface side of the semiconductor substrate.

### FIELD

The present invention relates to a solar battery cell, a manufacturing method thereof, and a solar battery module.

### BACKGROUND

Generally, conventional bulk-silicon solar battery cells for residential use or the like are manufactured by the following method. First, for example, a p-silicon substrate is prepared as a substrate of a first conduction type. A damage layer on a silicon surface generated when slicing the silicon substrate from a casting ingot is removed by a thickness of 10 micrometers to 20 micrometers with, for example, several to 20 wt % of caustic soda or carbonated sodium hydroxide.

Next, an irregular surface structure called texture is produced on a surface from which the damage layer is removed (see, for example, Patent Literature 1). On a surface side (a light-receiving surface side) of a solar battery cell, such texture is generally formed so as to suppress light reflection and to capture sunlight onto the p-silicon substrate as much as possible. Examples of a method of producing the texture include an alkaline texturing method. With the alkaline texturing method, a silicon substrate is anisotropically etched with a solution obtained by adding an additive such as IPA (isopropyl alcohol) that accelerates anisotropic etching to an alkaline solution such as a solution containing several wt % of caustic soda or carbonated sodium hydroxide, and the texture is formed so as to expose a silicon (111) plane.

As a diffusion treatment, a p-silicon substrate is treated for several dozen minutes at, for example, 800° C. to 900° C. in a mixed gas atmosphere of, for example, phosphorous oxychloride (POCl₃), nitrogen, and oxygen, thereby forming an n-layer uniformly on the entire surface as a dopant layer of a second conduction type. By setting the sheet resistance of the n-layer formed uniformly on the silicon surface to about 30Ω/□ to 80Ω/□, it is possible to obtain favorable electrical characteristics of a solar battery cell.

Because the n-layer is formed uniformly on the silicon surface, the surface is electrically connected to a back surface. To cut off this electrical connection, end surface regions of the p-silicon substrate are etched by dry etching, for example. As another method, the end surfaces of the p-silicon substrate are separated by laser. Thereafter, the p-silicon substrate is immersed in hydrofluoric acid, thereby etching away a glassy material (PSG) deposited on the surface during the diffusion treatment.

Next, an insulating film (an antireflection film) such as a silicon oxide film, a silicon nitride film, or a titanium oxide film is formed on the surface of the n-layer by a uniform thickness as an insulating film for antireflection purposes. When a silicon nitride film is formed as the antireflection film, the film is formed by using silane (SiH₄) gas and ammonia (NH₃) gas as raw materials under conditions of 300° C. or higher and a reduced pressure by using a plasma CVD method, for example. A refraction index of the antireflection film is about 2.0 to 2.2 and an optimum thickness thereof is about 70 nanometers to 90 nanometers. However, it is to be noted that an antireflection film formed in this way is an insulator and that the resultant layers do not function as a solar battery simply by forming surface electrodes on this film.

Next, using a mask for grid electrode formation and bus electrode formation, a silver paste that becomes the surface electrodes is applied onto the antireflection film into shapes of grid electrodes and bus electrodes by a screen printing method, and the silver paste is dried.

Next, a back-aluminum electrode paste that becomes back-aluminum electrodes and a back silver paste that becomes back silver bus electrodes are applied onto the back surface of the substrate into back-aluminum electrode shapes and back silver bus electrode shapes, respectively by a screen printing method, and the back-aluminum electrode paste is dried.

Next, the electrode pastes applied onto the surface and the back surface of the silicon substrate are fired simultaneously for a few minutes at about 600° C. to 900° C. Accordingly, grid electrodes and bus electrodes are formed as the surface electrodes on the antireflection film, and back-aluminum electrodes and back silver bus electrodes are formed on the back surface of the silicon substrate as back electrodes. In this case, on the surface side of the silicon substrate, a silver material contacts the silicon and re-solidifies while the antireflection film is molten by a glass material contained in the silver paste. This ensures the conduction between the surface electrodes and the silicon substrate (the n-layer). Such a process is referred to as “fire-through method”. The back-aluminum electrode paste also reacts to the back surface of the silicon substrate, thereby forming a p+ layer right under the back-aluminum electrodes.

To improve the photoelectric conversion efficiency of the bulk silicon solar battery cell formed as described above, it is important to optimize an irregular shape, that is, a texture shape on the surface of the substrate on the light-receiving surface side. Conventionally, as for the texture shape, bulk-silicon solar battery cells are produced so as to be able to realize the texture shape after optimization in a development phase.

### CITATION LIST

### Patent Literature

Patent Literature 1: Japanese Patent No. 4467218

### SUMMARY

### Technical Problem

However, various factors during a manufacturing process generate substrates the texture shapes of which deviate from an optimized shape. The optical reflectivity of a solar battery cell manufactured using such a substrate rises and the photoelectric conversion efficiency of the solar battery cell degrades eventually. For these reasons, problems occur that this solar battery cell cannot be shipped as a product and the yield of solar battery cells decreases. Furthermore, it is considered that etching is performed again by an alkaline texturing method with a view to re-form the texture shape in a case where the optical reflectivity of a solar battery cell formed by the alkaline texturing method is unfavorable. However, in this case, the optical reflectivity further degrades. Moreover, because a solar battery cell is used for a long period of time, it is also very important to ensure the reliability of the solar battery cell with which the power output of the solar battery cell can be maintained for a long period of time.

The present invention has been achieved to solve the above problems, and an object of the present invention is to achieve a solar battery cell, a manufacturing method thereof, and a solar battery module capable of preventing a degradation in photoelectric conversion efficiency resulting from a texture shape and excellent in photoelectric conversion efficiency, yield, and reliability.

### Solution to Problem

There is provided a solar battery cell according to an aspect of the present invention including: a semiconductor substrate of a first conduction type that includes a dopant diffusion layer on one surface side, a dopant element of a second conduction type being diffused into the dopant diffusion layer; a light-receiving surface side electrode that is electrically connected to the dopant diffusion layer and that is formed on the one surface side of the semiconductor substrate; and a back surface side electrode that is formed on the other surface side of the semiconductor substrate, wherein the solar battery cell has a first irregular shape on a surface on the other surface side of the semiconductor substrate, the solar battery cell has a second irregular shape that is provided on at least a part of a surface on the one surface side of the semiconductor substrate and that is lower in an optical reflectivity than the first irregular shape, and the one surface side of the semiconductor substrate is lower in the optical reflectivity than that on the other surface side of the semiconductor substrate.

### Advantageous Effects of Invention

According to the present invention, it is possible to achieve a solar battery cell excellent in photoelectric conversion efficiency, yield, and reliability.

### BRIEF DESCRIPTION OF DRAWINGS

FIG. 1-1 is a top view of a solar battery cell as viewed from a light-receiving surface side according to an embodiment of the present invention.

FIG. 1-2 is a bottom view of the solar battery cell as viewed from an opposite side to (a back surface side of) a light-receiving surface according to the present embodiment.

FIG. 1-3 is a cross-sectional view of relevant parts of the solar battery cell in an A-A direction in FIG. 1-1 according to the present embodiment.

FIG. 2 is a flowchart for explaining an example of a manufacturing process of a solar battery cell according to the present embodiment.

FIG. 3-1 is a cross-sectional view for explaining an example of the manufacturing process of a solar battery cell according to the present embodiment.

FIG. 3-2 is a cross-sectional view for explaining an example of the manufacturing process of a solar battery cell according to the present embodiment.

FIG. 3-3 is a cross-sectional view for explaining an example of the manufacturing process of a solar battery cell according to the present embodiment.

FIG. 3-4 is a cross-sectional view for explaining an example of the manufacturing process of a solar battery cell according to the present embodiment.

FIG. 3-5 is a cross-sectional view for explaining an example of the manufacturing process of a solar battery cell according to the present embodiment.

FIG. 3-6 is a cross-sectional view for explaining an example of the manufacturing process of a solar battery cell according to the present embodiment.

FIG. 3-7 is a cross-sectional view for explaining an example of the manufacturing process of a solar battery cell according to the present embodiment.

FIG. 3-8 is a cross-sectional view for explaining an example of the manufacturing process of a solar battery cell according to the present embodiment.

FIG. 4 is a characteristic diagram of a result of a reliability test on solar battery cells and a relation between a photoelectric-conversion-efficiency degradation rate and a lowest optical reflectivity.

### DESCRIPTION OF EMBODIMENTS

Exemplary embodiments of a solar battery cell, a manufacturing method thereof, and a solar battery module according to the present invention will be explained below in detail with reference to the accompanying drawings. The present invention is not limited to the following descriptions and can be modified as appropriate without departing from the scope of the invention. In addition, in the drawings explained below, for easier understanding, scales of respective members may be different from those of actual products. The same holds true for the relationships between respective drawings.

### Embodiment

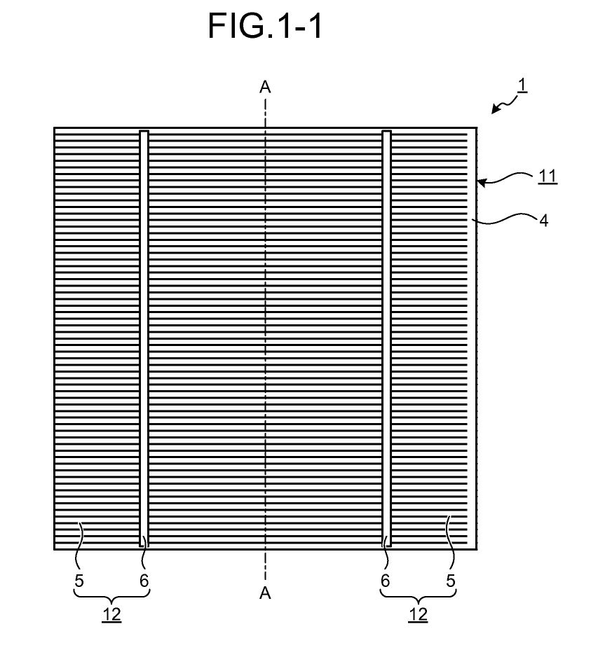

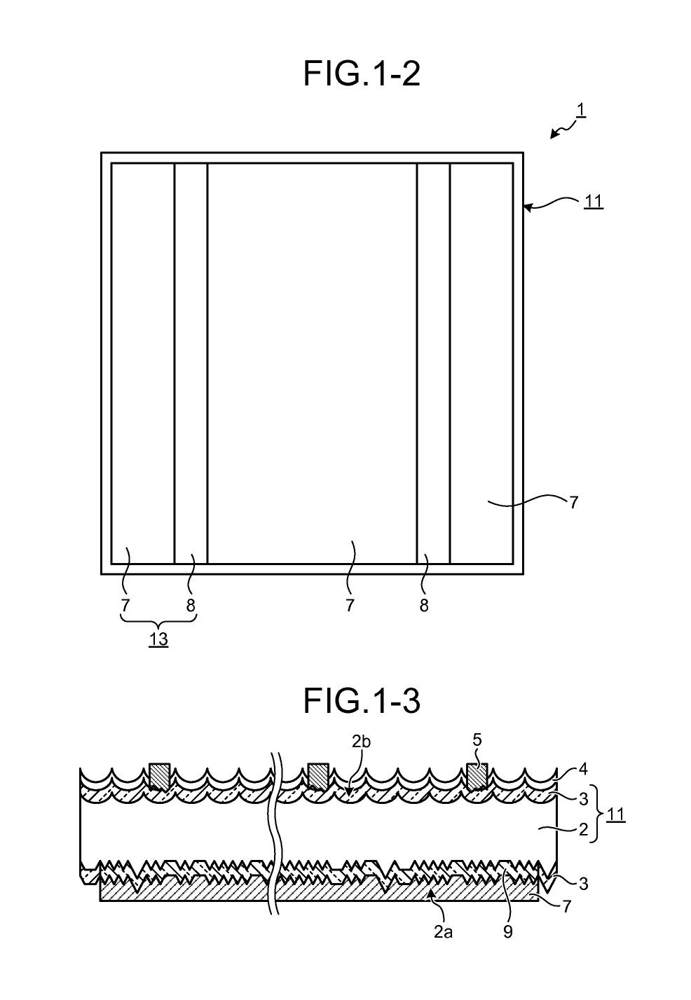

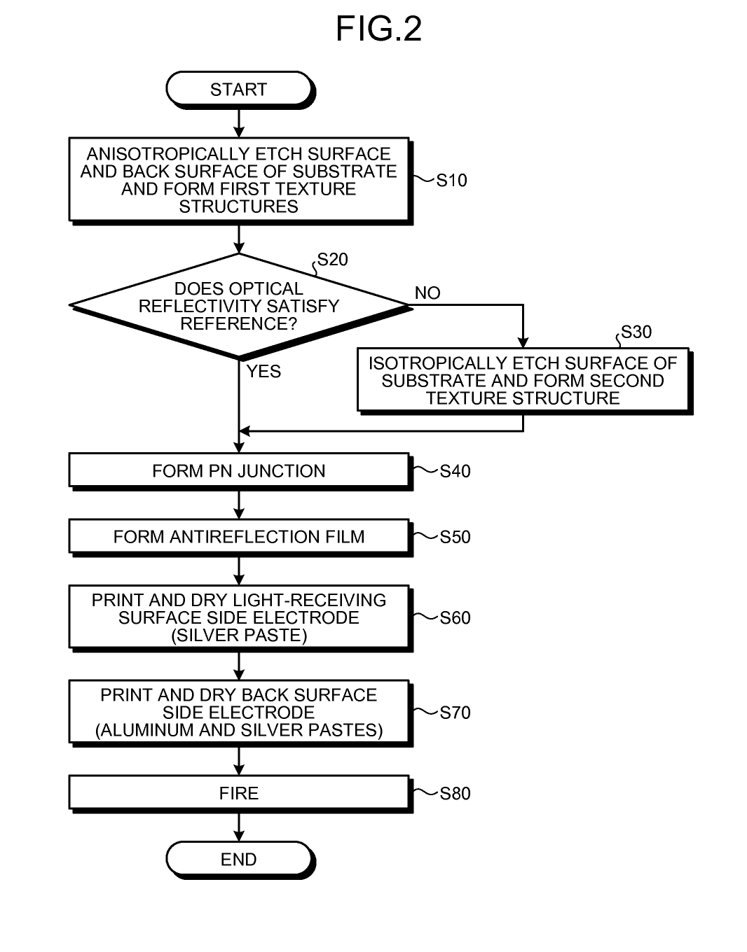

FIGS. 1-1 to 1-3 are explanatory diagrams of a configuration of a solar battery cell 1 according to an embodiment of the present invention. FIG. 1-1 is a top view of the solar battery cell 1 as viewed from a light-receiving surface side. FIG. 1-2 is a bottom view of the solar battery cell 1 as viewed from an opposite side to (a back surface side of) the light-receiving surface. FIG. 1-3 is a cross-sectional view of relevant parts of the solar battery cell 1 in an A-A direction in FIG. 1-1. The solar battery cell 1 is a silicon solar battery for residential use or the like.

In the solar battery cell 1 according to the present embodiment, an n-dopant diffusion layer 3 is formed on a light-receiving surface side of a semiconductor substrate 2 made of p-monocrystalline silicon by diffusing phosphorus, and a semiconductor substrate 11 having a pn junction is formed. Furthermore, an antireflection film 4 formed by a silicon nitride film (a SiN film) is formed on the n-dopant diffusion layer 3. The semiconductor substrate 2 is not limited to the p-monocrystalline silicon substrate but an n-monocrystalline silicon substrate can alternatively be used.

As shown in FIG. 1-3, a texture structure constituted by minute irregularities is formed on each of the surfaces on the light-receiving surface side (the n-dopant diffusion layer 3) and a back surface side of the semiconductor substrate 11. The texture structure is a structure that increases an area of a light-receiving surface by which the light-receiving surface absorbs light from outside, that suppresses an optical reflectivity of the light-receiving surface, and that confines the light.

In the solar battery cell 1 according to the present embodiment, the texture structures are formed on the light-receiving surface side and the back surface side of the semiconductor substrate 11 with each structure having a different shape. A first texture structure 2a having an exposed silicon (111) plane and constituted by minute irregularities having a substantially quadrangular-pyramid shape is formed on the back surface side of the semiconductor substrate 11. A second texture structure 2b constituted by bowl-like (substantially hemispherical) minute irregularities is formed on the light-receiving surface side of the semiconductor substrate 11. The shapes of the bowl-like (substantially hemispherical) minute irregularities of the second texture structure 2b are formed by etching the substantially quadrangular-pyramid-shaped minute irregularities of the first texture structure 2a as described later. The bowl-like (substantially hemispherical) texture shape of the second texture structure 2b can realize a lower optical reflectivity than that of the substantially quadrangular-pyramid texture shape of the first texture structure 2a.

The second texture structure 2b has a lower optical reflectivity than that of the first texture structure 2a. That is, in the solar battery cell 1 according to the present embodiment, the texture structures constituted by minute irregularities are formed on the light-receiving surface side and the back surface side of the semiconductor substrate 11 with each texture structure having a different shape. The texture shape on the light-receiving surface side of the semiconductor substrate 11 has a lower optical reflectivity than that of the texture shape on the back surface side of the semiconductor substrate 11.

The antireflection film 4 is formed by an insulating film such as a silicon nitride film (a SiN film), a silicon oxide film (a SiO₂ film), or a titanium oxide film (a TiO₂ film) for antireflection purposes. On the light-receiving surface side of the semiconductor substrate 11, a plurality of long and thin surface-silver grid electrodes 5 are provided side by side, surface-silver bus electrodes 6 conductive to these surface-silver grid electrodes 5 are provided to be substantially orthogonal to the surface-silver grid electrodes 5, and a bottom portion of each of the electrodes 5 and 6 is electrically connected to the n-dopant diffusion layer 3. The surface-silver grid electrodes 5 and the surface-silver bus electrodes 6 are constituted by a silver material.

For example, the surface-silver grid electrodes 5 are about 100 micrometers to 200 micrometers wide, are arranged in substantial parallel at an interval of about 2 millimeters, and collect currents generated within the semiconductor substrate 11. For example, the surface-silver bus electrodes 6 are about 1 millimeter to 3 millimeters wide, the number of surface-silver bus electrodes 6 arranged per solar battery cell is two to four, and the surface-silver bus electrodes 6 draw the currents collected by the surface-silver grid electrodes 5 to outside. The surface-silver grid electrodes 5 and the surface-silver bus electrodes 6 constitute a light-receiving surface side electrode 12 that serves as a first electrode. It is desirable to make an area of the light-receiving surface side electrode 12 as small as possible with a view to improve the power generation efficiency because the light-receiving surface side electrode 12 cuts off sunlight incident on the semiconductor substrate 11. The surface-silver grid electrodes 5 and the surface-silver bus electrodes 6 are generally arranged as the comb-like surface-silver grid electrodes 5 and bar-like surface-silver bus electrodes 6, respectively as shown in FIG. 1-1.

A silver paste is generally used as an electrode material of the light-receiving surface side electrode of the silicon solar battery cell and lead-boron glass, for example, is added to the silver plate. This glass is fritted glass and a composition of the fritted glass is, for example, 5 wt % to 30 wt % of lead (Pb), 5 wt % to 10 wt % of boron (B), 5 wt % to 15 wt % of silicon (Si), and 30 wt % to 60 wt % of oxygen (O), and about several wt % of zinc (Zn) and about several wt % of cadmium (Cd) may be mixed with the composition of the glass. Such lead-boron glass has properties of being dissolved when heated at hundreds of ° C. (800° C., for example) and eroding the silicon at the time of dissolution. Furthermore, generally, in a manufacturing method of a crystalline silicon solar battery cell, a method of establishing electrical contact between the silicon substrate and the silver paste by using the properties of this glass frit is adopted.

On the other hand, a back-aluminum electrode 7 made of an aluminum material is provided entirely on the back surface (a surface opposite to the light-receiving surface) of the semiconductor substrate 11, and back-silver electrodes 8 extending in substantially the same direction as that of the surface-silver bus electrodes 6 and made of a silver material are provided. The back-aluminum electrode 7 and the back-silver electrodes 8 constitute a back surface side electrode 13 serving as a second electrode. Moreover, the back-aluminum electrode 7 is expected to prohibit a BSR (Back Surface Reflection) effect of reflecting long-wavelength light passing through the semiconductor substrate 11 and reusing the reflected long-wavelength light for power generation.

Generally, silver is used as a material of the above light-receiving surface side electrode 12, aluminum is used as a material of the back surface side electrode, and a material mainly containing silver is often used in a part of regions of the back surface side electrode as needed from viewpoints of low cost and improvement in performance.

Furthermore, a p+ layer (a BSF (Back Surface Field) 9 containing highly-concentrated dopants is formed on a surface layer portion on the back surface side (an opposite surface to the light-receiving surface) of the semiconductor substrate 11. The p+ layer (the BSF) 9 is provided to obtain a BSF effect and increase an electron concentration of the p-layer (the semiconductor substrate 2) in an electric field of a band structure so that electrons within the p-layer (the semiconductor substrate 2) do not annihilate.

In the solar battery cell 1 configured as described above, when sunlight is irradiated from the light-receiving side of the solar battery cell 1 onto a pn junction surface of the semiconductor substrate 11 (a junction surface between the semiconductor substrate 2 and the n-dopant diffusion layer 3), holes and electrons are generated. The generated electrons move toward the n-dopant diffusion layer 3 and the generated holes move toward the p+ layer 9 by an electric field of the pn junction. As a result, excessive electrons are present in the n-dopant diffusion layer 3 and excessive holes are present in the p+ layer 9, thereby generating photovoltaic power. This photovoltaic power is generated in a direction of biasing the pn junction in a forward direction. The light-receiving surface side electrode 12 connected to the n-dopant diffusion layer 3 functions as a negative electrode and the back-aluminum electrode 7 connected to the p+ layer 9 functions as a positive electrode, and a current thereby flows to an external circuit (not shown).

In the solar battery cell 1 according to the present embodiment configured as described above, texture structures are formed on the light-receiving surface side and the back surface side of the semiconductor substrate 11 with each texture structure having a different shape. The texture shape on the light-receiving surface side of the semiconductor substrate 11 has a lower optical reflectivity than that of the texture shape on the back surface side of the semiconductor substrate 11. That is, in the solar battery cell 1 according to the present embodiment, the first texture structure 2a having an exposed silicon (111) plane and constituted by minute irregularities having a substantially quadrangular-pyramid shape is formed on the back surface side of the semiconductor substrate 11. The second texture structure 2b constituted by bowl-like (a substantially hemispherical) minute irregularities is formed on the light-receiving surface side of the semiconductor substrate 11.

Because the bowl-like (substantially hemispherical) texture shape of the second texture structure 2b has a lower optical reflectivity than that of the substantially quadrangular-pyramid texture shape of the first texture structure 2a, a favorable optical reflectivity can be obtained on the light-receiving surface side of the semiconductor substrate 11 in the solar battery cell 1 according to the present embodiment and a reduction in the photoelectric conversion efficiency resulting from the texture shape can be prevented. This can improve the photoelectric conversion efficiency of the solar battery cell 1. Furthermore, by providing the second texture structure 2b on the light-receiving surface side of the semiconductor substrate 11, the solar battery cell 1 according to the present embodiment is ensured to have high reliability with which the photoelectric conversion efficiency can be maintained for a long period of time.

Moreover, the second texture structure 2b is formed by reprocessing the texture shape of the first texture structure 2a, which is formed by an alkaline texturing method, by an acid texturing method. Accordingly, the solar battery cell 1 having a favorable photoelectric conversion efficiency can be realized by using the substrate the first texture structure 2a of which has an insufficient optical reflectivity, and the solar battery cell having a high yield is realized. Therefore, the solar battery cell 1 according to the present embodiment can realize a solar battery cell excellent in photoelectric conversion efficiency, yield, and reliability.

The present embodiment has been explained above with reference to the silicon solar battery using the monocrystalline silicon substrate as the semiconductor substrate as an example. However, the present invention can achieve effects identical to those described above even when a substrate made of a material other than silicon is used as the semiconductor substrate as long as texture structures are formed on the surface side and the back surface side of the substrate with each texture structure having a different shape, and the texture structure on the light-receiving surface side of the semiconductor substrate has a lower optical reflectivity than that of the texture structure on the back surface side of the semiconductor substrate 11.

The manufacturing method of the solar battery cell 1 according to the present embodiment is described with reference to the drawings. FIG. 2 is a flowchart for explaining an example of a manufacturing process of the solar battery cell 1 according to the present embodiment. FIGS. 3-1 to 3-8 are cross-sectional views for explaining an example of the manufacturing process of the solar battery cell 1 according to the present embodiment. FIGS. 3-1 to 3-8 are cross-sectional views of relevant parts corresponding to FIG. 1-3.

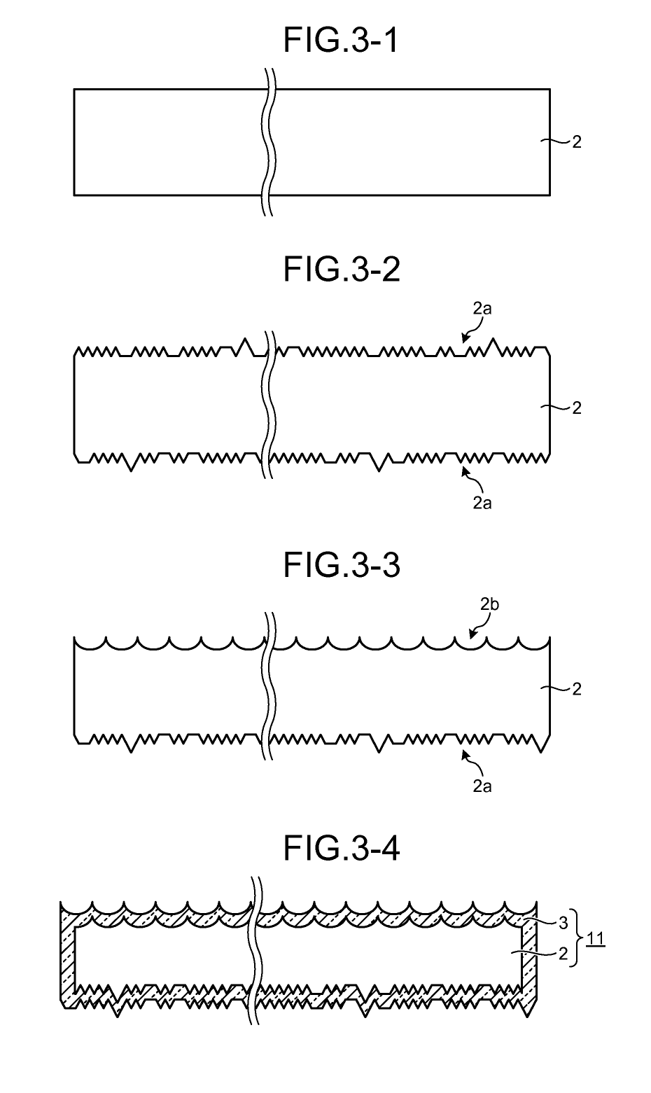

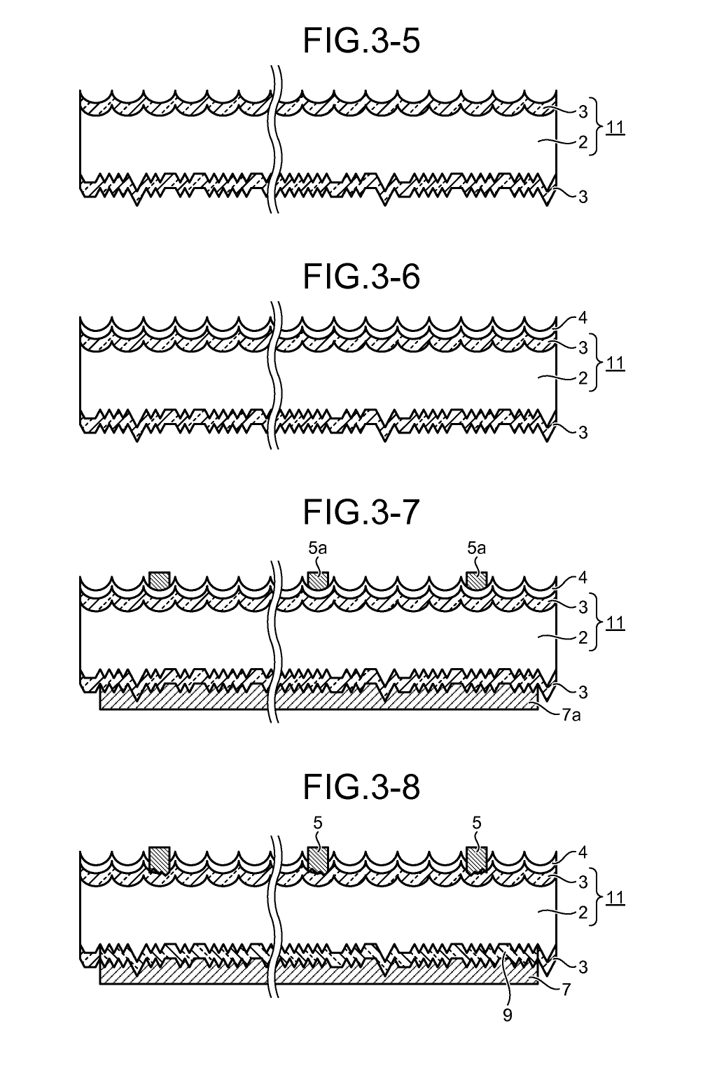

First, a p-monocrystalline silicon substrate having a thickness of, for example, hundreds of micrometers is prepared as the semiconductor substrate 2 (FIG. 3-1). Because the p-monocrystalline silicon substrate is manufactured by slicing an ingot obtained by cooling and solidifying molten silicon by using a wire saw, damages generated at a time of slicing remain on a surface of the p-monocrystalline silicon substrate. Therefore, the p-monocrystalline silicon substrate is immersed in acid or heated alkaline solution, for example, aqueous sodium hydroxide and the surface of the p-monocrystalline silicon substrate is etched, thereby removing damaged regions generated at the time of slicing the silicon substrate and present near the surface of the p-monocrystalline silicon substrate. For example, the surface of the p-monocrystalline silicon substrate is removed by a thickness of 10 micrometers to 20 micrometers by, for example, several to 20 wt % of caustic soda or carbonated sodium hydroxide. As the p-silicon substrate used as the semiconductor substrate 2, a p-monocrystalline silicon substrate having a specific resistance of 0.1 Ω·cm to 5 Ω·cm and a (100) plane orientation is described as an example.

Subsequently to removing the damages, the p-monocrystalline silicon substrate is anisotropically etched with a solution obtained by adding an additive such as IPA (isopropyl alcohol) that accelerates anisotropic etching to an alkaline solution similarly having a low concentration of alkali such as a solution containing several wt % of caustic soda or sodium hydrogen carbonate. As a result of this anisotropic etching, minute irregularities having a substantially quadrangular-pyramid shape are formed on surfaces on a light-receiving-side and a back surface side of the p-monocrystalline silicon substrate, respectively so as to expose the silicon (111) plane, thereby forming the first texture structure 2a as the first texture structure (Step S10, FIG. 3-2). That is, the texture structure is formed on each of the surface and the back surface of the p-monocrystalline silicon substrate by wet etching using an alkaline solution (an alkaline texturing method).

Next, an optical-reflectivity measurement device measures the optical reflectivity of each of the surface and the back surface of the p-monocrystalline silicon substrate on which the first texture structure 2a is formed, respectively, and it is determined whether the optical reflectivity satisfies a predetermined reference (Step S20). A texturing process is further performed to the p-monocrystalline silicon substrate the optical reflectivity of which does not satisfy the predetermined reference in the measurement of the optical reflectivity.

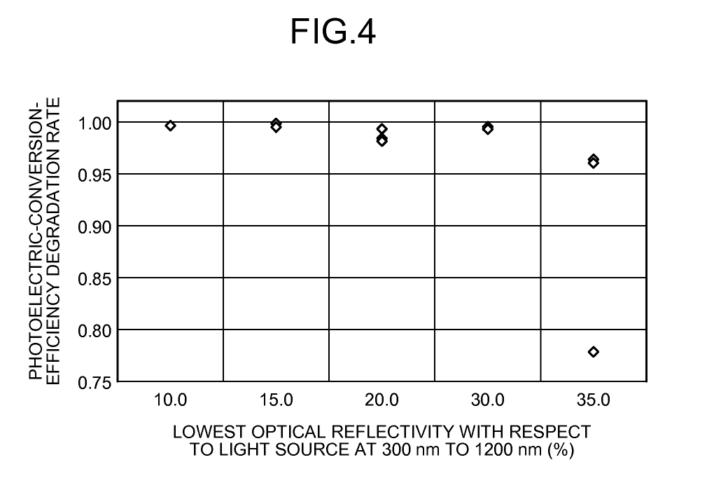

The predetermined reference is assumed as an optical reflectivity of 30% or less with respect to a light source at 300 nanometers to 1200 nanometers, for example. It is very important to ensure the reliability of the solar battery cell because the solar battery cell is used for a long period of time. As a result of a reliability test conducted on many solar battery cells by the present inventor, it was found that the optical reflectivity after the formation of the texture structure correlates to the result of the reliability test. The reliability test was conducted by accelerating a degradation in each solar battery cell, in which the texture structure 2a was formed on the surface and the back surface of the p-monocrystalline silicon substrate, in a high temperature and high humidity state equal to or higher than that in a natural environment. FIG. 4 depicts a result of the test. FIG. 4 is a characteristic diagram of the result of the reliability test on the solar battery cells and a relation between a photoelectric-conversion-efficiency degradation rate and a lowest optical reflectivity.

The photoelectric-conversion-efficiency degradation rate in FIG. 4 is obtained by dividing the photoelectric conversion efficiency of each solar battery cell after the reliability test by that of the solar battery cell before the reliability test. As the lowest optical reflectivity on a horizontal axis, a lowest value was adopted as a typical value among the optical reflectivities with respect to a light source at a wavelength of 300 nanometers to 1200 nanometers. As can be understood from FIG. 4, the reliability degrades when the optical reflectivity is higher than 30%. This result indicates that the solar battery cell, which is manufactured by using the p-monocrystalline silicon substrate the optical reflectivity of which with respect to the light source at the wavelength of 300 nanometers to 1200 nanometers is higher than 30%, is possibly insufficient in the reliability.

After the treatment of forming the texture structures by the alkaline texturing method, when the optical reflectivity does not satisfy a predetermined value (NO at Step S20), a treatment of forming the texture structure is performed to the surface of the p-monocrystalline silicon substrate by wet etching using an acidic solution (hereinafter, “acid texturing method”). Etching on the p-monocrystalline silicon substrate by the acid texturing method is isotropic etching differently from the etching on the p-monocrystalline silicon substrate by the alkaline texturing method. Accordingly, the p-monocrystalline silicon substrate is uniformly etched without depending on the plane orientation of the surface of the p-monocrystalline silicon substrate. Therefore, the etching based on the acid texturing method proceeds uniformly without the influence of a state of the surface of the p-monocrystalline silicon substrate.

As a result, all or a part of the first texture structure the optical reflectivity of which is not favorable is isotropically etched by re-etching based on the acid texturing method, thereby forming the second texture structure 2b as the second texture structure (Step S30, FIG. 3-3). The texture shape of the second texture structure 2b is a bowl shape (a substantially hemispheric shape). The bowl-like (substantially hemispheric) texture shape of the second texture structure 2b has a lower optical reflectivity than that of the substantially quadrangular-pyramid texture shape of the first texture structure 2a. Therefore, by forming such a second texture structure 2b, it is possible to further reduce the optical reflectivity on the surface of the p-monocrystalline silicon substrate. That is, the optical reflectivity on the surface of the p-monocrystalline silicon substrate on which the second texture structure 2b is formed is lower than a case where the first texture structure 2a is formed on the surface of the p-monocrystalline silicon substrate.

In the present embodiment, the p-monocrystalline silicon substrate on which the first texture structure 2a is formed is floated on a mixed solution in which a volume ratio of a hydrogen fluoride to a nitric acid is 12 to 1 (a mixed solution of “hydrogen fluoride:nitric acid=12:1” in a volume ratio) for 10 seconds with the surface (the light-receiving surface side) facing downward. By thus etching only the surface while floating the p-monocrystalline silicon substrate on the acid chemical, it is possible to avoid heat generation during the etching and avoid excessive etching. Thereafter, to regulate the state of the etched surface, the p-monocrystalline silicon substrate is immersed in a dilute alkaline solution for 2 to 3 seconds.

After the etching based on the acid texturing method, the surface of the p-monocrystalline silicon substrate differs from the back surface thereof in an etched shape (a texture shape) to reflect etching characteristics of acid and alkali. That is, the texture shape of the first texture structure 2a is a substantially quadrangular-pyramid shape whereas that of the second texture structure 2b is a bowl shape (a substantially hemispheric shape). While FIG. 3-3 depicts that the texture shape on the surface side of the p-monocrystalline silicon substrate is entirely bowl-shaped, the shape is sometimes such that the texture shape of the first texture structure 2a partially remains depending on conditions for the acid texturing method. In this case, similarly to the above, the optical reflectivity of the overall texture structure on the surface side of the p-monocrystalline silicon substrate is lower than that of the first texture structure 2a on the back surface side thereof.

Furthermore, the etching based on the acid texturing method is not limited to the method using the mixed solution of hydrogen fluoride and nitric acid. There is a method that enables forming the second texture structure 2b capable of further reducing the optical reflectivity, for example, a method of performing the etching based on the acid texturing method after forming an etching mask having openings of desired shapes on the surface of the p-monocrystalline silicon substrate.

Moreover, for example, Journal of The Electrochemical Society, 146(2)457-461 (1999) describes that the etching controllability improves by adding phosphoric acid or acetic acid to an acid solution. Furthermore, this literature discloses a photograph of a surface shape etched by the acid texturing method by SEM observation. This photograph indicates that the texture shape is a bowl shape (a substantially hemispheric shape) by the etching based on the acid texturing method while the texture shape is a pyramid shape by the etching based on the alkaline texturing method.

However, when an optimum texture shape can be realized on the p-monocrystalline silicon substrate by the etching based on the alkaline texturing method, a lower optical reflectivity than that of the texture shape formed by the etching based on the acid texturing method can be obtained. Accordingly, in a general solar battery manufacturing process, wet etching using an acidic solution is not performed on the monocrystalline silicon substrate.

Moreover, when the etching based on the alkaline texturing method is performed again with a view to re-form the texture shape in a case where the optical reflectivity obtained by the etching based on the alkaline texturing method is not favorable, the optical reflectivity further degrades. This is because the alkaline texturing method is the anisotropic etching that proceeds with formation of the texture so as to expose the silicon (111) plane and is a treatment very sensitive to the substrate surface. Accordingly, when the first process is performed to make a surface state of the substrate into a state different from a state before the general etching, it is impossible to further reduce the optical reflectivity from that of the initially obtained texture structure. The state before a general etching is a state where the entire planes right after the slicing are (100) planes.

Next, the pn junction is formed on the semiconductor substrate 2 (Step S40, FIG. 3-4). That is, diffusion or the like of a group V element such as phosphorus (P) is performed on the semiconductor substrate 2, thereby forming the n-dopant diffusion layer 3 at a thickness of hundreds of nanometers. In this example, the pn junction is formed by diffusing the phosphorous oxychloride (POCl₃) on the p-monocrystalline silicon substrate on the surface of which the texture structure is formed by thermal diffusion. Accordingly, the semiconductor substrate 11 having the pn junction constituted by the semiconductor substrate 2 that is a layer of the first conduction type and that is made of p-monocrystalline silicon and the n-dopant diffusion layer 3 that is formed on the light-receiving surface side of the semiconductor substrate 2 and that is a layer of the second conduction type can be obtained.

In this diffusion process, the p-monocrystalline silicon substrate is subjected to thermal diffusion in a mixed gas atmosphere of, for example, phosphorus oxychloride (POCl₃) gas, nitrogen gas, and oxygen gas at a high temperature of, for example, 800° C. to 900° C. for several tens of minutes by a vapor-phase diffusion method, thereby uniformly forming the n-dopant diffusion layer 3 into which phosphorus (P) is diffused on the surface layer of the p-monocrystalline silicon substrate. When a sheet resistance of the n-dopant diffusion layer 3 formed on the surface of the semiconductor substrate 2 falls within a range from about 30Ω/□ to 80∩/□, it is possible to obtain favorable electrical characteristics of a solar battery.

The n-dopant diffusion layer 3 is formed on the entire surface of the semiconductor substrate 2. Accordingly, the surface (the light-receiving surface) and the back surface of the semiconductor substrate 2 are in a state of being electrically connected to each other. Therefore, to cut off this electrical connection, end regions of the semiconductor substrate 2 are etched by dry etching (FIG. 3-5), for example. Furthermore, a glassy material (PSG: Phospho-Silicate Glass) layer deposited on the surface during the diffusion treatment is formed on the surface right after forming the n-dopant diffusion layer 3. Accordingly, the PSG layer is etched away by immersing the semiconductor substrate 2 in the aqueous sodium hydroxide or the like.

Next, the antireflection film 4 is formed on the entire surface of the light-receiving surface side of the semiconductor substrate 11 by a uniform thickness so as to improve the photoelectric conversion efficiency (Step S50, FIG. 3-6). The thickness and a refraction index of the antireflection film 4 are set to values at which the antireflection film 4 can maximally suppress the light reflection. To form the antireflection film 4, a silicon nitride film is formed as the antireflection film 4 using mixed gas of silane (SiH₄) gas and ammonia (NH₃) gas as raw materials under conditions of 300° C. or higher and a reduced pressure by using a plasma CVD method, for example. The refraction index of the antireflection film 4 is, for example, about 2.0 to 2.2 and an optimum thickness of the antireflection film 4 is 70 nanometers to 90 nanometers. Furthermore, the antireflection film 4 has a surface shape taking over from the texture shape of the second texture structure 2b.

Alternatively, as the antireflection film 4, two or more films having different refraction indexes can be stacked. As a method of forming the antireflection film 4, an evaporation method, a thermal CVD method, or the like can be used besides the plasma CVD method. However, it should be noted that the antireflection film 4 formed in this way is an insulator and that the resultant layers do not function as a solar battery cell simply by forming the light-receiving surface side electrode 12 on this antireflection film 4.

Electrodes are then formed by screen printing. First, the light-receiving surface side electrode 12 is produced (before firing). That is, after applying a silver paste, which is an electrode material paste containing a glass frit, on the antireflection film 4 serving as the light-receiving surface of the semiconductor substrate 11 into shapes of the surface-silver grid electrodes 5 and the surface-silver bus electrodes 6 by screen printing, the silver paste is dried (Step S60, FIG. 3-7). FIG. 3-7 depicts only a silver paste 5a applied and dried into the shapes of the surface-silver grid electrodes 5.

Next, an aluminum paste 7a that is an electrode material paste is applied onto the back surface side of the semiconductor substrate 11 into the shape of the back-aluminum electrode 7 by screen printing. A silver paste that is an electrode material paste is applied onto the back surface side of the semiconductor substrate 11 into the shapes of the back-silver electrodes 8. The aluminum paste 7a and the silver paste are dried (Step S70, FIG. 3-7). FIG. 3-7 depicts only the aluminum paste 7a.

The aluminum paste 7a is applied almost entirely onto the back surface of the semiconductor substrate 11. Accordingly, it is difficult to determine the texture shape formed by the etching based on the alkaline texturing method. However, to prevent leakage of the aluminum paste 7a, regions where the aluminum paste 7a is not applied are generally provided on outer peripheral portions of the back surface of the semiconductor substrate 11. Therefore, in the regions where this aluminum paste 7a is not applied, the texture shape on the back surface of the semiconductor substrate 11 can be confirmed.

Thereafter, the electrode pastes on the surface and the back surface of the semiconductor substrate 11 are simultaneously fired at 600° C. to 900° C., for example. Accordingly, the silver material contacts the silicon and re-solidifies while the antireflection film 4 is molten by the glass material contained in the silver paste on the surface side of the semiconductor substrate 11. The surface-silver grid electrodes 5 and the surface-silver bus electrodes 6 serving as the light-receiving surface side electrode 12 are thereby obtained, which ensures the conduction between the light-receiving surface side electrode 12 and the silicon of the semiconductor substrate 11 (Step S80, FIG. 3-8). Such a process is referred to as “fire-through method”.

Furthermore, the aluminum paste 7a similarly reacts to the silicon of the semiconductor substrate 11 to obtain the back-aluminum electrode 7, and the p+ layer 9 is formed right under the back-aluminum electrode 7. The silver material of the silver paste contacts the silicon and re-solidifies, thereby obtaining the back-silver electrodes 8 (FIG. 3-8). FIG. 3-8 depicts only the surface-silver grid electrodes 5 and the back-aluminum electrode 7.

By performing the above processes, the solar battery cell 1 according to the present embodiment shown in FIGS. 1-1 to 1-3 is obtained. An order of arranging the pastes that are the electrode materials on the semiconductor substrate 11 can be transposed between the light-receiving surface side and the back surface side.

Further, when the optical reflectivity satisfies the desired value after the treatment of forming the texture structure by the alkaline texturing method (YES at Step S20), the processes at Steps S40 to S80 are performed similarly to the conventional technique without performing Step S30. A solar battery cell with the first texture structure 2a formed on the light-receiving surface side and the back surface side, respectively, is thereby obtained.

In the manufacturing method of a solar battery cell according to the present embodiment described above, the texture structures are formed on the light-receiving surface side and the back surface side of the semiconductor substrate 11 with each texture structure having a different shape. The texture structure on the light-receiving surface side of the semiconductor substrate 11 has a lower optical reflectivity than that of the texture structure on the back surface side of the semiconductor substrate 11. That is, in the manufacturing method of a solar battery cell according to the present embodiment, the first texture structure 2a having the exposed silicon (111) plane and constituted by minute irregularities having a substantially quadrangular-pyramid shape is formed on the back surface side of the semiconductor substrate 11 by an alkaline texturing method. The second texture structure 2b constituted by bowl-like (substantially hemispherical) minute irregularities is formed on the light-receiving surface side of the semiconductor substrate 11 by the acid texturing method after executing the alkaline texturing method.

By performing the processes of forming such texture structures, even when the optical reflectivity of the first texture structure 2a formed on the light-receiving surface side of the semiconductor substrate 11 by an alkaline texturing method is insufficient and the solar battery cell is inappropriate as a product, a favorable optical reflectivity can be achieved on the light-receiving surface side of the semiconductor substrate 11 by reprocessing the texture shape and a reduction in the photoelectric conversion efficiency resulting from the texture shape can be prevented. This can improve the photoelectric conversion efficiency of the solar battery cell 1.

Even when the optical reflectivity of the first texture structure 2a formed by an alkaline texturing method is insufficient, it is possible to manufacture the solar battery cell 1 having a favorable photoelectric conversion efficiency by reprocessing the texture shape by an acid texturing method. It is thereby possible to commercialize a high-quality solar battery cell without discarding the substrate having the first texture structure 2a that is formed by an alkaline texturing method and the optical reflectivity of which is insufficient, and to improve the yield.

Furthermore, there is a correlation between the optical reflectivity derived from the texture structure and the reliability, and the solar battery cell 1 the optical reflectivity of which is low on the light-receiving surface side has high reliability. In the manufacturing method of a solar battery cell according to the present embodiment, because it is possible to manufacture the solar battery cell 1 having a low optical reflectivity on the light-receiving surface side by providing the texture structure as described above, it is possible to manufacture the solar battery cell 1 having high reliability for a long period of time. Therefore, according to the manufacturing method of a solar battery cell of the present embodiment, it is possible to manufacture a solar battery cell excellent in the photoelectric conversion efficiency, yield, and reliability.

Further, by arraying a plurality of solar battery cells 1 each having the configuration described in the above embodiment and electrically connecting the adjacent solar battery cells 1 either in series or in parallel, it is possible to realize a solar battery module having a favorable light confining effect and excellent in reliability and photoelectric conversion efficiency. In this case, it suffices to electrically connect the surface-silver bus electrodes 6 of one of the adjacent solar battery cells to the back-silver electrodes 8 of another solar battery cell. A lamination process of covering these solar battery cells with an insulating layer and laminating these solar battery cells is performed. With this process, a solar battery module constituted by the solar battery cells 1 is manufactured.

### INDUSTRIAL APPLICABILITY

As described above, the solar battery cell according to the present invention is useful for realizing a solar batter cell that is excellent in photoelectric conversion efficiency, yield, and reliability.

### REFERENCE SIGNS LIST

1 solar battery cell
2 semiconductor substrate
2a first texture structure
2b second texture structure
3 n-dopant diffusion layer
4 antireflection film
5 surface-silver grid electrode
5a silver paste
6 surface-silver bus electrode
7 back-aluminum electrode
7a aluminum paste
8 back-silver electrode
9 p+ layer (BSF)
11 semiconductor substrate
12 light-receiving surface side electrode
13 back surface side electrode

1. A solar battery cell comprising:
a semiconductor substrate of a first conduction type that includes a dopant diffusion layer on one surface side that is a light-receiving surface side, a dopant element of a second conduction type being diffused into the dopant diffusion layer;
a light-receiving surface side electrode that is electrically connected to the dopant diffusion layer and that is formed on the one surface side of the semiconductor substrate; and
a back surface side electrode that is formed on the other surface side of the semiconductor substrate, the other surface side being opposite to the light-receiving surface side, wherein
the solar battery cell has a first irregular shape entirely on a surface on the other surface side of the semiconductor substrate,
the solar battery cell has a second irregular shape that is provided on at least a part of a surface on the one surface side of the semiconductor substrate and that is lower in an optical reflectivity than the first irregular shape, and has the first irregular shape in all regions where the second irregular shape is not formed, on the surface on the one surface side of the semiconductor substrate, and
the one surface side of the semiconductor substrate is lower in the optical reflectivity than that on the other surface side of the semiconductor substrate.

2. (canceled)

3. The solar battery cell according to claim 1, wherein
the semiconductor substrate is a monocrystalline silicon substrate,
the first irregular shape is constituted by substantially quadrangular-pyramid irregularities, and
the second irregular shape is constituted by substantially hemispherical irregularities.

4. The solar battery cell according to claim 1, wherein
a lowest optical reflectivity with respect to a light source of a wavelength of 300 nanometers to 1200 nanometers on the other surface side of the semiconductor substrate is higher than 30%, and
a lowest optical reflectivity with respect to the light source of a wavelength of 300 nanometers to 1200 nanometers on the one surface side of the semiconductor substrate is equal to or lower than 30%.

5. A manufacturing method of a solar battery cell comprising:
a first step of anisotropically etching one surface side that serves as a light-receiving surface side and the other surface side opposite to the light-receiving surface side of a semiconductor substrate of a first conduction type, and of forming a first irregular shape entirely on each of the one surface side and the other surface side of the semiconductor substrate;
a second step of forming a dopant diffusion layer by diffusing a dopant element of a second conduction type to the one surface side of the semiconductor substrate on which the first irregular shape is formed,
a third step of forming an electrode electrically connected to the dopant diffusion layer on the one surface side of the semiconductor substrate; and
a fourth step of forming an electrode electrically connected to the other surface side of the semiconductor substrate, wherein
between the second step and the third step, a second irregular shape lower in an optical reflectivity than the first irregular shape is formed on the one surface side of the semiconductor substrate by isotropically etching the one surface side of the semiconductor substrate and processing at least a part of the first irregular shape when the optical reflectivity on the one surface side of the semiconductor substrate on which the first irregular shape is formed is measured and the measured optical reflectivity does not satisfy a predetermined reference that the optical reflectivity with respect to a light source of a wavelength of 300 nanometers to 1200 nanometers is equal to or lower than 30%, and
the third step is performed to the semiconductor substrate on which the second irregular shape is formed on the one surface side.

6. (canceled)

7. The manufacturing method of a solar battery cell according to claim 5, wherein
the semiconductor substrate is a monocrystalline silicon substrate,
at the first step, the first irregular shape constituted by substantially quadrangular-pyramid irregularities is formed by wet etching using an alkaline solution, and
at the second step, the second irregular shape constituted by substantially hemispherical irregularities is formed by wet etching using an acid solution.

8. The manufacturing method of a solar battery cell according to claim 5, wherein
a lowest optical reflectivity with respect to a light source of a wavelength of 300 nanometers to 1200 nanometers on the other surface side of the semiconductor substrate is higher than 30%, and
a lowest optical reflectivity with respect to the light source of a wavelength of 300 nanometers to 1200 nanometers on the one surface side of the semiconductor substrate is equal to or lower than 30%.

9. A solar battery module, wherein at least two or more of the solar battery cells according to claim 1 are electrically connected in series or in parallel.
